(19) United States
(12) Patent Application Publication
(10) Pub. No.: US 2014/0302428 A1
(43) Pub. Date: Oct. 9, 2014

(54) MASK FOR FABRICATING SEMICONDUCTOR DEVICE AND METHOD OF FABRICATING THE MASK

(71) Applicant: Samsung Electronics Co., Ltd., Suwon-si (KR)

(72) Inventors: So-Eun Shin, Hwaseong-si (KR); Byunggook Kim, Seoul (KR); Jihyeon Choi, Hwaseong-si (KR)

(73) Assignee: Samsung Electronics Co., Ltd., Suwon-si (KR)

(21) Appl. No.: 14/095,090

(22) Filed: Dec. 3, 2013

(30) Foreign Application Priority Data
Apr. 8, 2013 (KR) 1020130038167

(51) Int. Cl. G03F 1/80

(52) U.S. Cl. CPC G03F 1/80
USPC 430/5

(57) ABSTRACT

A photo-mask for fabricating a semiconductor device may include a transparent substrate including a main region, a supplementary region adjacent to the main region, a main pattern for developing circuits in a semiconductor device provided on the main region of the transparent substrate, and a supplementary pattern for optical proximity correction provided on the supplementary region of the transparent substrate. The main pattern has a sidewall perpendicular to a surface of the transparent substrate, and the supplementary pattern has a sidewall inclined to the surface of the transparent substrate and an upward tapered structure.

### CROSS-REFERENCE TO RELATED APPLICATIONS

This U.S. non-provisional patent application claims priority under 35 U.S.C. §119 to Korean Patent Application No. 10-2013-0038167, filed on Apr. 8, 2013, in the Korean Intellectual Property Office, the entire contents of which are hereby incorporated by reference.

### BACKGROUND OF THE INVENTION

Exemplary embodiments in accordance with principles of inventive concepts relate to a photo-mask and a fabrication method thereof, and in particular, to a mask for fabricating a semiconductor device and a method of fabricating the mask.

To form fine patterns (for example, in a semiconductor device), a photolithography technology providing a large focus margin may be prepared. Due to a variety of pattern widths and pattern pitches, a region of the semiconductor device may include regions of both high and low pattern density. Due to differences in diffraction properties between the regions of high and low pattern densities, it may be difficult to achieve enough focus margin to simultaneously form high-density patterns and low-density patterns on a semiconductor wafer. This difficulty may increase with decreasing pattern size of the semiconductor device.

To address such difficulties, an optical proximity correction (OPC) method using a sub-resolution assist feature (SRAF) may be employed. In the OPC method, at least one supplementary pattern is provided near a main pattern. The supplementary pattern is formed at a region having a low pattern density, thereby improving a depth-of-focus (DOF) of the main pattern. According to the OPC method, a scattering bar or the supplementary pattern is formed on a transparent substrate, like the main pattern, but an image thereof is not transferred onto the wafer. That is, the main pattern forms a functional area in an image but the supplementary pattern merely enhances the functional area formed in the image.

### SUMMARY

In exemplary embodiments in accordance with principles of inventive concepts A photo-mask, includes a transparent substrate including a main region and a supplementary region adjacent to the main region; a main pattern to define a functional pattern provided on the main region of the transparent substrate; and a supplementary pattern to provide optical proximity correction provided on the supplementary region of the transparent substrate, wherein the main pattern includes a sidewall perpendicular to a surface of the transparent substrate, and the supplementary pattern includes a sidewall inclined to the surface of the transparent substrate forming an upward tapered structure.

In exemplary embodiments in accordance with principles of inventive concepts the angle between the surface of the transparent substrate and a sidewall of the supplementary pattern is from 45° to 85°.

In exemplary embodiments in accordance with principles of inventive concepts, the main pattern and the supplementary pattern include chromium or molybdenum silicide.

In exemplary embodiments in accordance with principles of inventive concepts the main pattern and the supplementary pattern are chromium-containing patterns, the transparent substrate further comprises a peripheral region surrounding the main region and the supplementary region, and the mask further comprises a prevention, or, in exemplary embodiments, light-prevention, pattern disposed on the peripheral region of the transparent substrate, the prevention, or, in exemplary embodiments, light-prevention, pattern being a chromium-containing pattern.

In exemplary embodiments in accordance with principles of inventive concepts the main pattern and the supplementary pattern include molybdenum-silicide-containing patterns, the transparent substrate further comprises a peripheral region surrounding the main region and the supplementary region, the mask further comprises a peripheral pattern and a prevention pattern sequentially stacked on the peripheral region of the transparent substrate, the peripheral pattern including a molybdenum silicide, the prevention pattern including chromium.

In exemplary embodiments in accordance with principles of inventive concepts a method of fabricating a photo mask, includes preparing a transparent substrate including a main region, a supplementary region adjacent to the main region, and a peripheral region surrounding the main region and the supplementary region; and forming a main pattern, a supplementary pattern, and a prevention pattern on the main region, the supplementary region, and the peripheral region, respectively, of the transparent substrate, wherein the main pattern is formed to have a sidewall perpendicular to a surface of the transparent substrate, and the supplementary pattern is formed to have a sidewall inclined to the surface of the transparent substrate to form an upward tapered structure.

In exemplary embodiments in accordance with principles of inventive concepts the angle between the surface of the transparent substrate and the sidewall of the supplementary pattern is from 45° to 85°.

In exemplary embodiments in accordance with principles of inventive concepts the forming of the main pattern, the supplementary pattern, and the prevention pattern comprises forming a mask layer on the transparent substrate; forming a first photoresist pattern on the mask layer to expose a portion of the main region and cover the supplementary region and the peripheral region; etching the mask layer using the first photoresist pattern as a mask to form the main pattern and the prevention pattern; removing the first photoresist pattern; forming a second photoresist pattern on the transparent substrate, in which with the main pattern and the prevention pattern are formed, to expose a portion of the supplementary region and cover the main region and the peripheral region; etching the mask layer using the second photoresist pattern as a mask to form the supplementary pattern; and removing the second photoresist pattern.

In exemplary embodiments in accordance with principles of inventive concepts the mask layer is formed of chromium or molybdenum silicide.

In exemplary embodiments in accordance with principles of inventive concepts the mask layer is formed of molybdenum silicide, and the method further comprises forming a prevention layer on the mask layer, before forming the first photoresist pattern.

In exemplary embodiments in accordance with principles of inventive concepts the prevention layer is formed of chromium.

In exemplary embodiments in accordance with principles of inventive concepts a method includes forming a third photoresist pattern on the prevention layer to expose a portion of the main region and a portion of the supplementary region and cover the peripheral region; etching the prevention layer using the third photoresist pattern as a mask to form a main mask pattern, a supplementary mask pattern and an additional prevention pattern on the main region, the supplementary region, and the peripheral region, respectively, of the mask layer; and removing the third photoresist pattern.

In exemplary embodiments in accordance with principles of inventive concepts the forming of the main pattern comprises etching the mask layer using the main mask pattern and the first photoresist pattern wholly exposing the main region as an etch mask.

In exemplary embodiments in accordance with principles of inventive concepts the forming of the supplementary pattern comprises etching the mask layer using the supplementary mask pattern and the second photoresist pattern wholly exposing the supplementary region as an etch mask.

In exemplary embodiments in accordance with principles of inventive concepts after the removing of the third photoresist pattern, further comprising removing the main mask pattern on the main pattern and the supplementary mask pattern on the supplementary pattern.

In exemplary embodiments in accordance with principles of inventive concepts a photo-mask includes a transparent substrate; a main pattern to define a functional pattern on the substrate; and an optical proximity correction pattern on the substrate, wherein the optical proximity correction pattern is upwardly tapering.

In exemplary embodiments in accordance with principles of inventive concepts sidewalls of the optical proximity correction pattern form an acute angle with the surface of the transparent substrate.

In exemplary embodiments in accordance with principles of inventive concepts the main and optical proximity correction patterns include chromium or molybdenum silicide.

In exemplary embodiments in accordance with principles of inventive concepts a photo mask includes a prevention pattern on a peripheral region of the transparent substrate surrounding the main and optical proximity correction patterns.

In exemplary embodiments in accordance with principles of inventive concepts the prevention pattern includes chromium.

### BRIEF DESCRIPTION OF THE DRAWINGS

Exemplary embodiments in accordance with principles of inventive concepts will be more clearly understood from the following brief description taken in conjunction with the accompanying drawings. The accompanying drawings represent non-limiting, exemplary embodiments.

FIG. 1 is a schematic perspective view illustrating a mask for fabricating a semiconductor device, according to exemplary embodiments in accordance with principles of inventive concepts.

FIG. 2 is a schematic perspective view illustrating a mask for fabricating a semiconductor device, according to other exemplary embodiments in accordance with principles of inventive concepts.

FIGS. 3A through 3E are sectional views illustrating a method of fabricating a mask, according to exemplary embodiments in accordance with principles of inventive concepts.

FIGS. 4A through 4J are sectional views illustrating a method of fabricating a mask, according to other exemplary embodiments in accordance with principles of inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example, may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

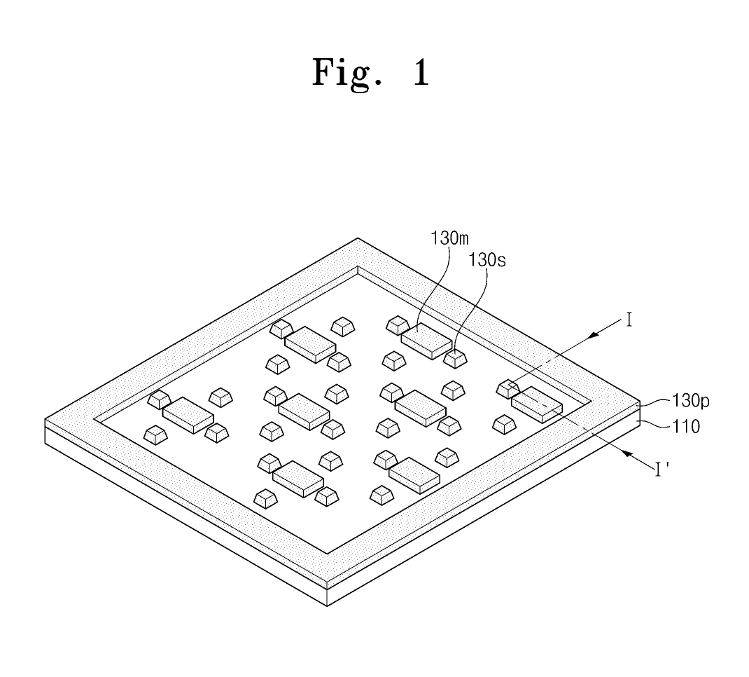

FIG. 1 is a schematic perspective view illustrating a mask for fabricating a semiconductor device, according to exemplary embodiments in accordance with principles of inventive concepts. A mask for fabricating a semiconductor device (hereinafter, referred as to a “mask”) may include a transparent substrate 110, and a main pattern 130m, a supplementary pattern 130s and a prevention, or, in exemplary embodiments, light-prevention, pattern 130p provided on a surface of the transparent substrate 110.

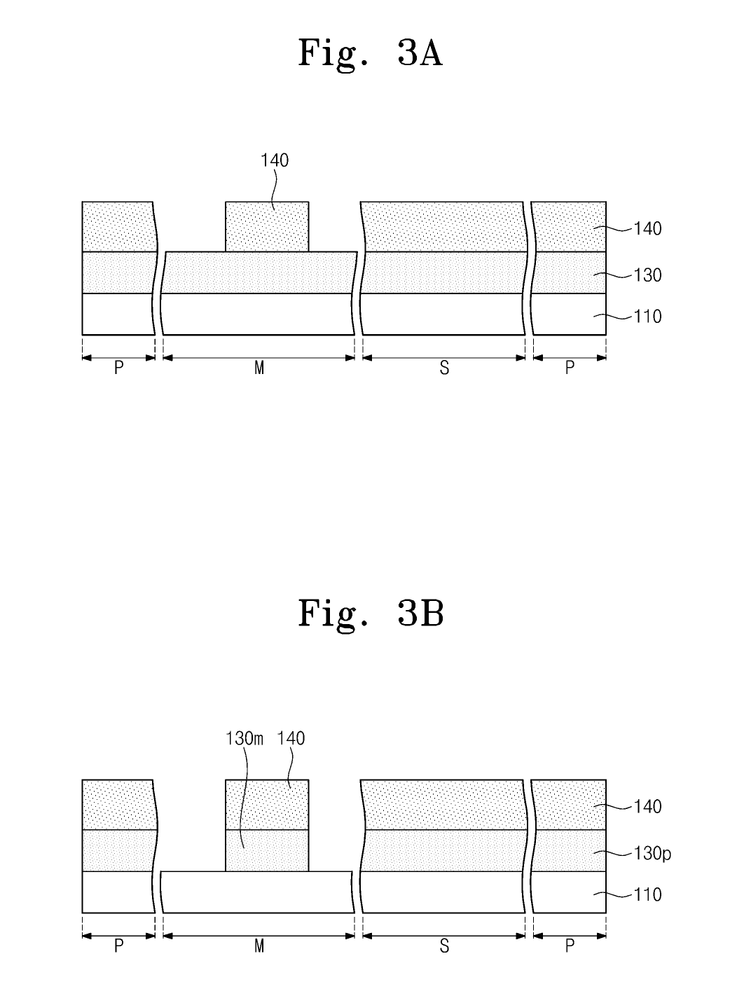

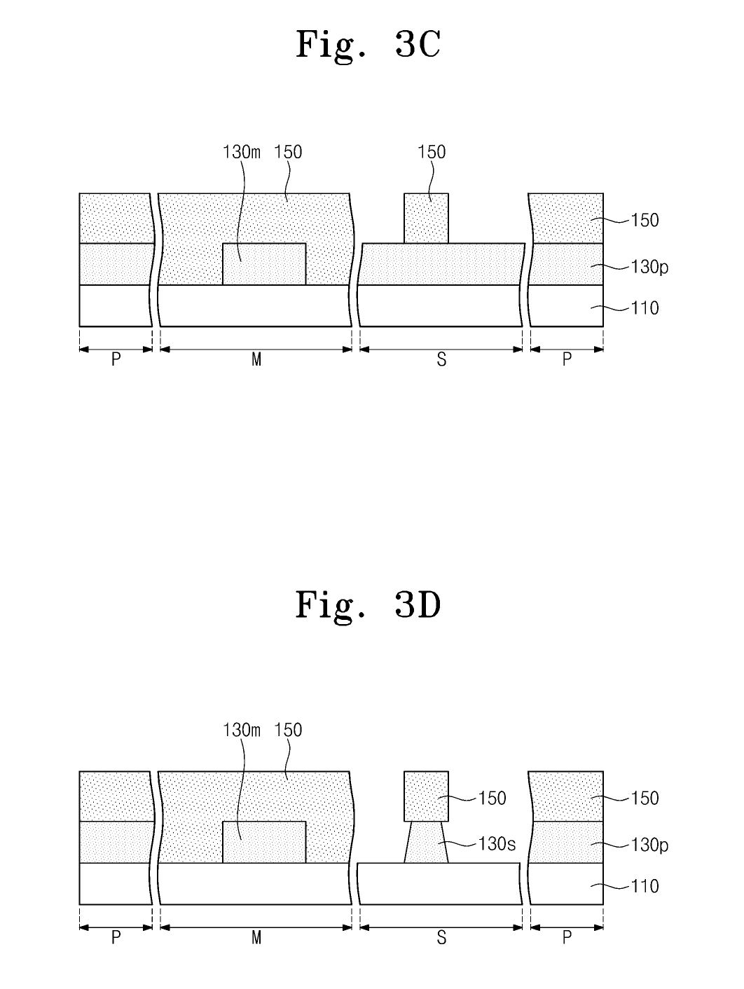

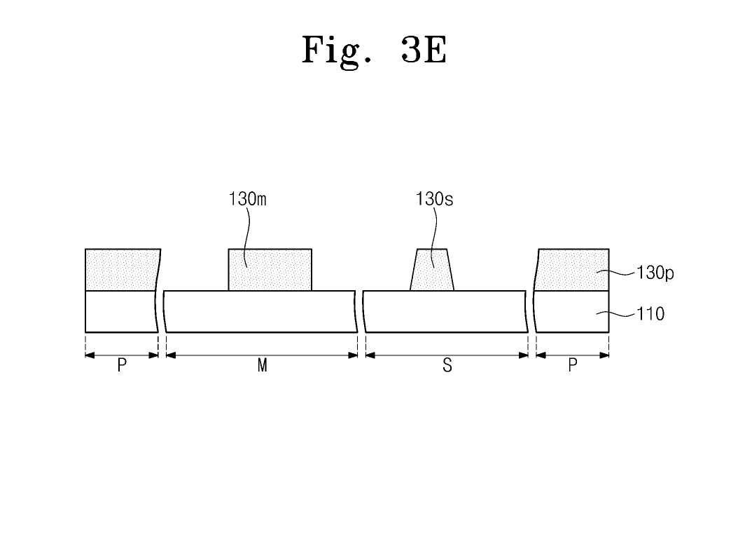

The transparent substrate 110 may include a main region M (of FIG. 3E), on which the main pattern 130m may be disposed, a supplementary region S (of FIG. 3E), on which the supplementary pattern 130s may be disposed, and a peripheral region P (of FIG. 3E), on which the prevention pattern 130p may be disposed. The peripheral region may surround the main region and the supplementary region, for example. The transparent substrate 110 may include quartz or glass, for example.

The main pattern 130m may define a pattern shape to be transferred onto a wafer. The supplementary pattern 130s may be for an optical proximity correction and, as such the shape of the supplementary pattern 130s may not be transferred on to the wafer. The prevention pattern 130p may prevent light from being incident onto the peripheral region of the transparent substrate 110. In example embodiments, the supplementary pattern 130s may feature narrower line-widths than the main pattern 130m. For example, the supplementary pattern 130s may be configured to have a maximum width of about 50 nm. The main pattern 130m, the supplementary pattern 130s, and the prevention pattern 130p may be of the same height.

In the mask, the main pattern 130m and the supplementary pattern 130s may include a material having an optical transmissivity of about 0. For example, the main pattern 130m, the supplementary pattern 130s, and the prevention pattern 130p may include chromium (Cr). Accordingly, the mask may be a binary-type mask.

In accordance with principles of inventive concepts, the main pattern 130m and the supplementary pattern 130s adjacent thereto may be grouped together to serve as a single pattern in order to reduce the optical proximity effect.

In accordance with principles of inventive concepts, main pattern 130m may have a sidewall that is perpendicular to a surface of the transparent substrate 110 and the supplementary pattern 130s may have a sidewall inclined to the surface of the transparent substrate 110. In exemplary embodiments in accordance with principles of inventive concepts, the width of the supplementary pattern 130s, or elements thereof, may decrease with increasing distance from the transparent substrate 110 and angle between the sidewall of the supplementary pattern 130s and the surface of the transparent substrate 110 may range from 45° to 85°, for example. When referring to characteristics of patterns herein, those characteristics may refer to elements of patterns. That is, for example, when referring to decreasing width(s) of patterns, reference may be to decreasing widths of elements of the patterns, for example. Similarly, when referring to a pattern that is perpendicular to, or at an angle to, a plane, reference may be to elements of patterns that are perpendicular to, or at an angle to, a plane.

Although an inclined sidewall of the supplementary pattern 130m in accordance with principles of inventive concepts may lead to a variation in a critical dimension (CD) of patterns to be formed on a wafer, experiments indicate that such a variation may be no more than about 1 nm. Limited variation in CD such as this indicates that a practical lithography process using the mask may not be appreciably affected by the presence of the supplementary pattern 130m in accordance with principles of inventive concepts.

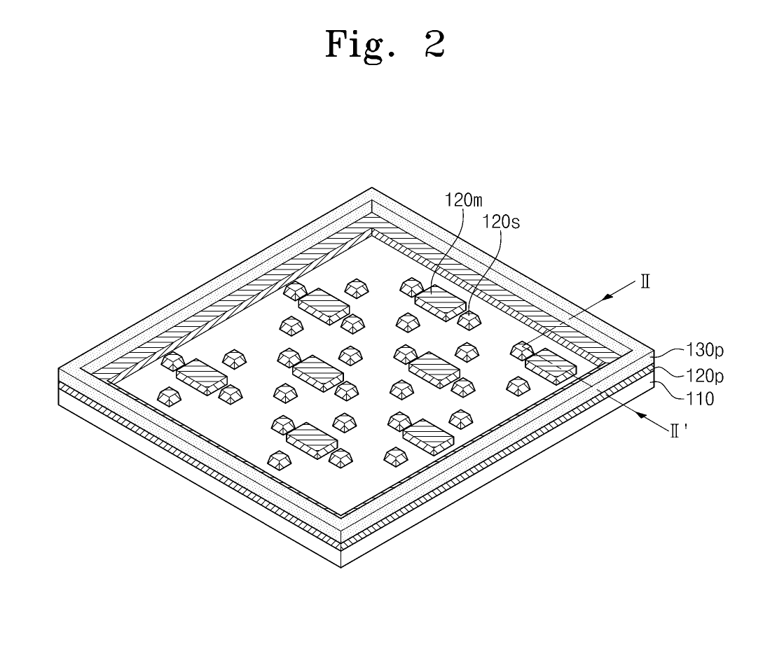

An exemplary embodiment of a mask for fabricating a semiconductor device in accordance with principles of inventive concepts will be described with reference to FIG. 2, which is a schematic perspective view illustrating a mask for fabricating a semiconductor device, according to exemplary embodiments in accordance with principles of inventive concepts. For clarity and economy of description, previously described element may be identified by a similar or identical reference number without repeating a description thereof.

Referring to FIG. 2, a mask according to other exemplary embodiments in accordance with principles of inventive concepts may include a main pattern 120m, a supplementary pattern 120s, and a peripheral pattern 120p. The mask may differ from that of the previous embodiments, in that materials for the main pattern 120m, the supplementary pattern 120s, and the peripheral pattern 120p may be different from those of previous exemplary embodiments, for example, and may further include the prevention pattern 130p on the peripheral pattern 120p.

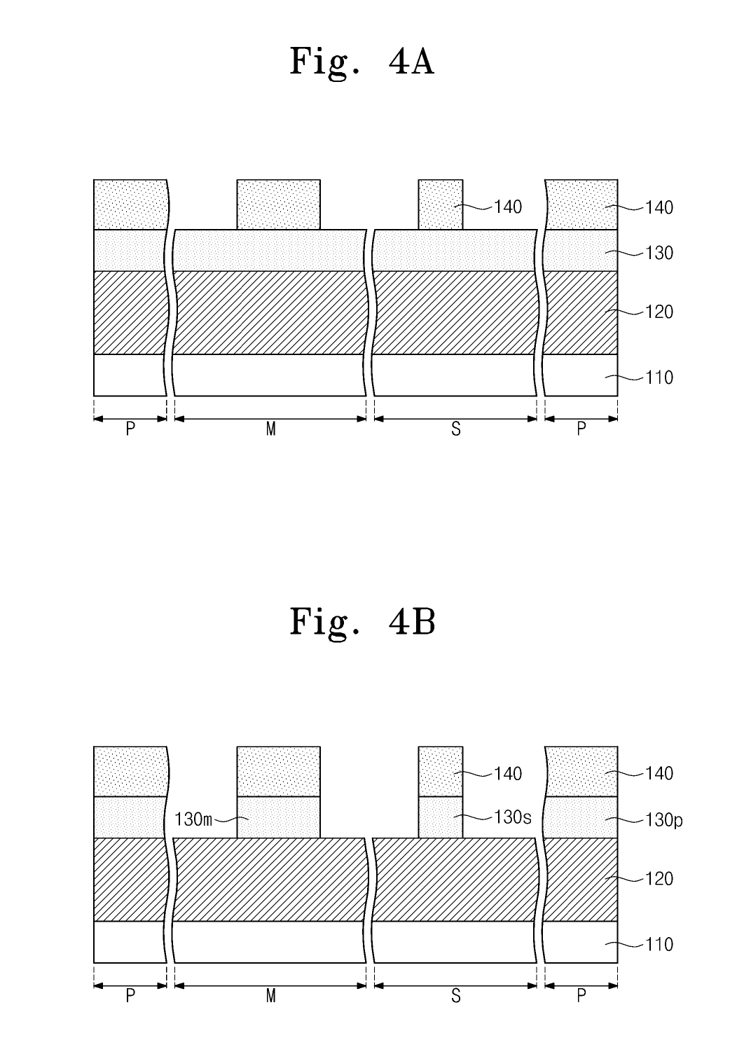

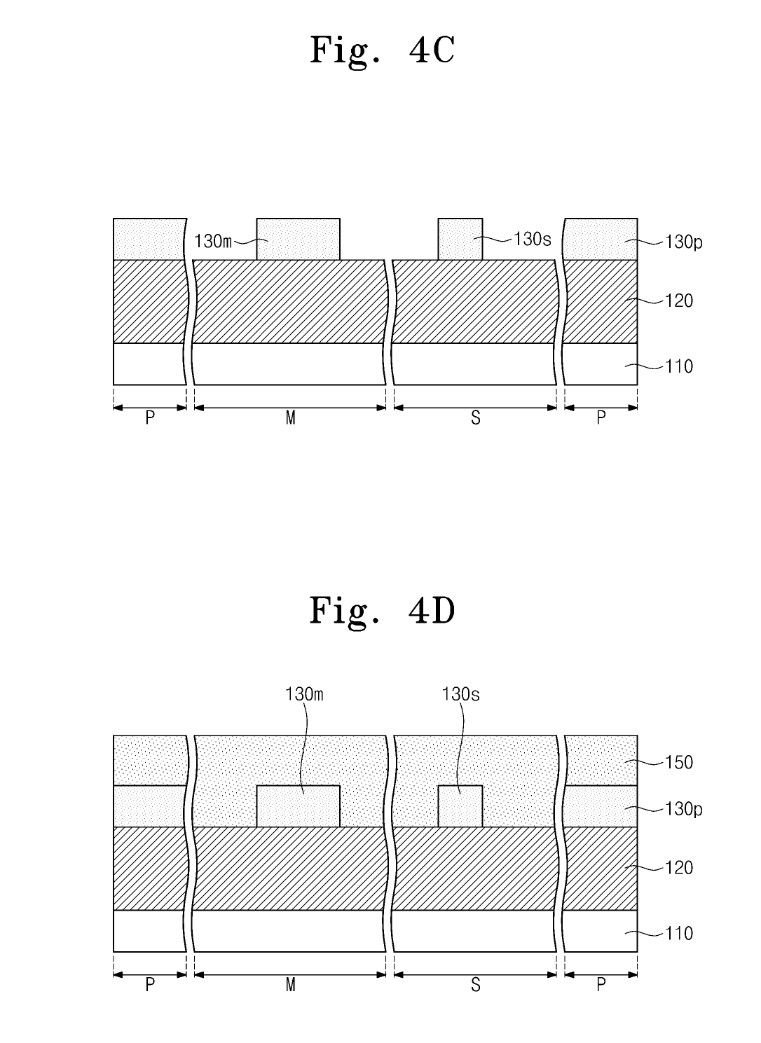

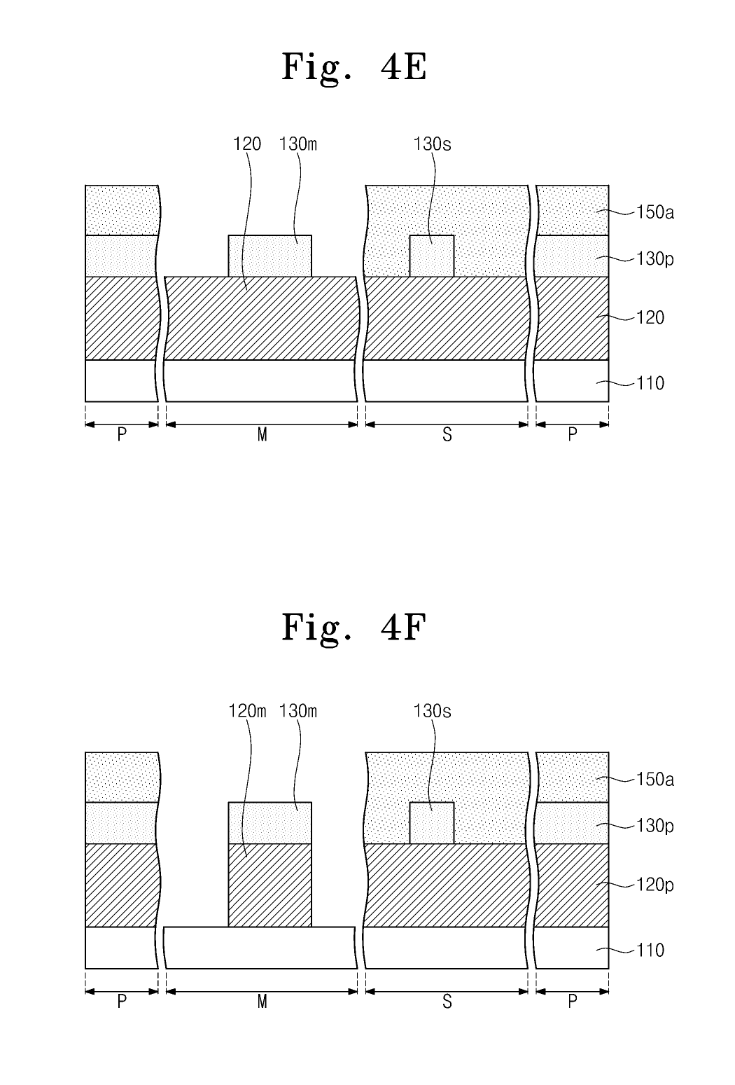

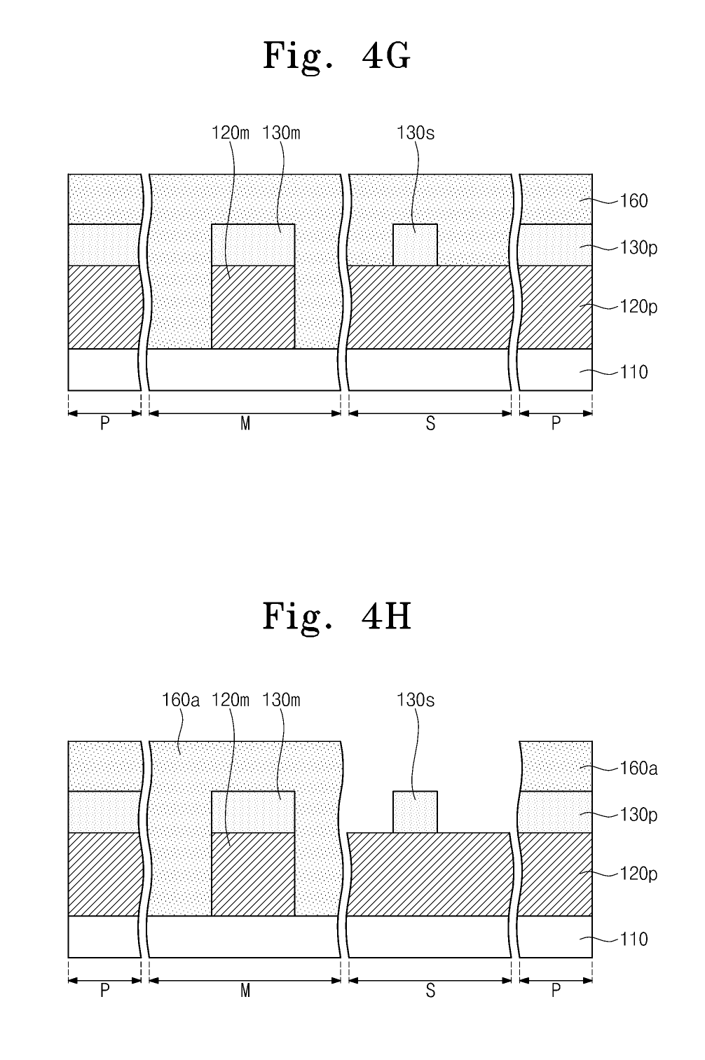

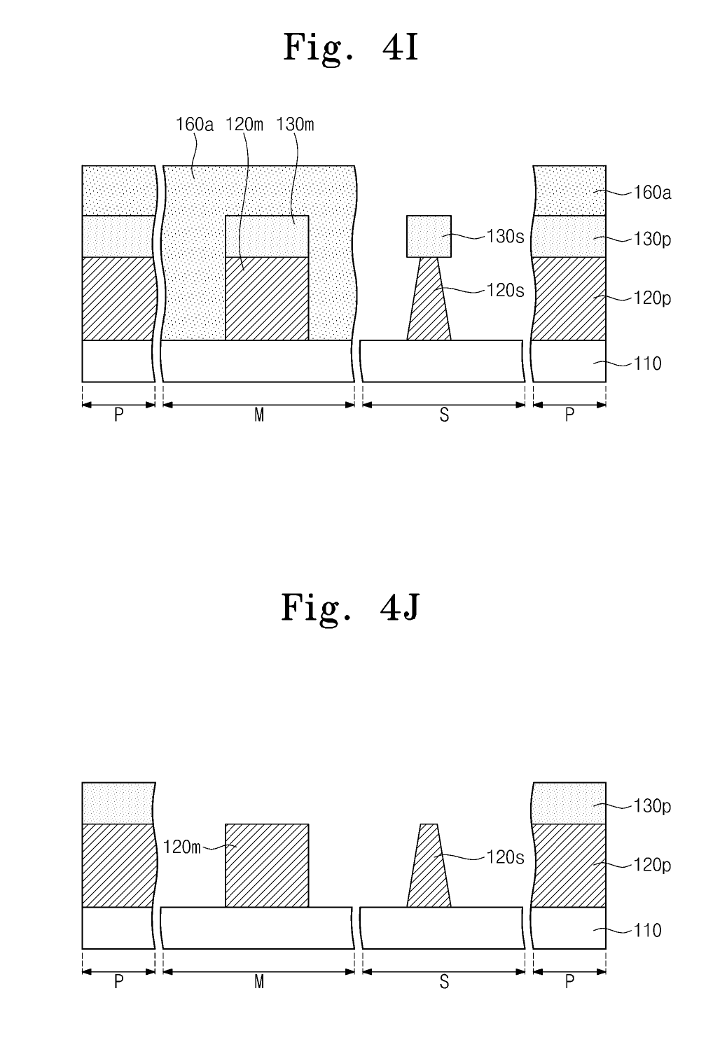

The transparent substrate 110 may include a main region M (of FIG. 4J), on which the main pattern 120m may be disposed, a supplementary region S (of FIG. 4J), on which the supplementary pattern 120s may be disposed, and a peripheral region P (of FIG. 4J), on which the peripheral pattern 120p and the prevention pattern 130p may be disposed. The peripheral region may surround the main region and the supplementary region.

In exemplary embodiments in accordance with principles of inventive concepts, main pattern 120m may have a sidewall that is perpendicular to the surface of the transparent substrate 110, and the supplementary pattern 120s may have a sidewall inclined to the surface of the transparent substrate 110. For example, the width of the supplementary pattern 120s, or of elements thereof, may decrease with increasing distance from the transparent substrate 110. In example embodiments, an angle between the sidewall of the supplementary pattern 120s and the surface of the transparent substrate 110 may range from 45° to 85°, for example.

In accordance with principles of inventive concepts, the main pattern 120m, the supplementary pattern 120s, and the peripheral pattern 120p may include molybdenum silicide (MoSi). The mask may further include the prevention pattern 130p provided on the peripheral pattern 120p. Although the molybdenum silicide may have an optical transmissivity of about 6%, the prevention pattern 130p may enable complete blockage of light through the peripheral region of the transparent substrate 110. The prevention pattern 130p may include chromium.

A mask according to other exemplary embodiments in accordance with principles of inventive concepts may be used to realize a phase shift type mask, taking advantage of the fact that the main pattern 120m and the supplementary pattern 120s include molybdenum silicide, whose optical transmissivity is about 6%.

Because, in accordance with principles of inventive concepts the supplementary pattern, or elements thereof, may be configured to have a decreasing width with increasing distance from the transparent substrate, or an upward tapered structure, the supplementary pattern can have an improved endurance to a cleaning process. Accordingly, the use of a mask with a supplementary pattern in accordance with principles of inventive concepts may make it possible to improve the resolution of a photolithography process, for example.

FIGS. 3A through 3E are sectional views illustrating an exemplary method of fabricating a mask, according to exemplary embodiments in accordance with principles of inventive concepts. For example, FIGS. 3A through 3E may be sectional views taken along a line I-I′ of FIG. 1.

Referring to FIG. 3A, transparent substrate 110 may be prepared, including the main region M, the supplementary region S adjacent to the main region M, and the peripheral region P surrounding the main region M and the supplementary region S. The transparent substrate 110 may include quartz or glass, for example.

A mask layer 130 may be formed on a surface of the transparent substrate 110. The mask layer 130 may be formed of chromium, for example.

A first photoresist pattern 140 may be formed on the mask layer 130 to expose a portion of the main region M and cover the supplementary region S and the peripheral region P.

Referring to FIG. 3B, the mask layer 130 may be etched using the first photoresist pattern 140 as an etch mask to form the main pattern 130m and the prevention pattern 130p. In accordance with principles of inventive concepts main pattern 130m may be formed to have a sidewall that is perpendicular to the surface of the transparent substrate 110.

Referring to FIG. 3C, the first photoresist pattern 140 may be removed, and then, a second photoresist pattern 150 may be formed on the transparent substrate 110 provided with the main pattern 130m and the prevention pattern 130p to expose a portion of the supplementary region S and cover the main region M and the peripheral region P.

Referring to FIG. 3D, the mask layer 130 may be etched using the second photoresist pattern 150 as an etch mask to form the supplementary pattern 130s. The supplementary pattern 130s may be formed to have a sidewall inclined to the surface of the transparent substrate 110. That is, in accordance with principles of inventive concepts, sidewalls of elements of the supplementary pattern 130s may be inclined to the surface of substrate 110. For example, the supplementary pattern 130s, or elements thereof, may be formed to have a width decreasing with increasing distance from the transparent substrate or an upward tapered structure. In example embodiments, an angle between the sidewall of the supplementary pattern 130s and the surface of the transparent substrate 110 may range from 45° to 85° (that is, for example, an angle that is from 45□ to 5□ with respect to a perpendicular to transparent substrate 110)

In exemplary embodiments in accordance with principles of inventive concepts, the formation of the supplementary pattern 130s may be performed by an etching process using an etch recipe different from that for forming the main pattern 130m. For example, between the etching processes for forming the supplementary pattern 130s and the main pattern 130m, there may be a difference in a process condition associated with an etch bias. Such a difference makes it possible to realize the inclined sidewall of the supplementary pattern 130s.

Referring to FIG. 3E, the second photoresist pattern 150 may be removed, and then, a cleaning process may be performed to the mask including the main pattern 130m, the supplementary pattern 130s and the prevention pattern 130p provided on the transparent substrate 110.

Because the supplementary pattern 130s, or elements thereof, may be configured to have the width decreasing with increasing distance from the transparent substrate, thereby forming an upward tapered structure, the supplementary pattern 130s may exhibit an improved endurance to the cleaning process. For example, an upward-tapered structure in accordance with principles of inventive concepts may prevent detachment of the supplementary pattern 130s during the cleaning process.

Hereinafter, a method of fabricating a mask, according to other exemplary embodiments in accordance with principles of inventive concepts will be described with reference to FIGS. 4A through 4J. FIGS. 4A through 4J are sectional views illustrating a method of fabricating a mask, according to other exemplary embodiments in accordance with principles of inventive concepts. FIGS. 4A through 4J may be sectional views taken along a line II-II′ of FIG. 2, for example. For clarity and conciseness of description, previously described elements may be identified by a similar or identical reference number without repeating a description thereof.

A mask fabricating method in accordance with principles of inventive concepts to be described with reference to FIGS. 4A through 4J may differ from the previous method described with reference to FIGS. 3A through 3E, in that materials for the main pattern 120m, the supplementary pattern 120s, and the peripheral pattern 120p may be different from those of the previous embodiments. Additionally, in the exemplary embodiment of FIGS. 4A through 4J, prevention pattern 130p is formed on the peripheral pattern 120p.

Referring to FIG. 4A, transparent substrate 110 is prepared, including the main region M, the supplementary region S adjacent to the main region M, and the peripheral region P surrounding the main region M and the supplementary region S. The transparent substrate 110 may include quartz or glass, for example.

A mask layer 120 may be formed on a surface of the transparent substrate 110 and may be formed of molybdenum silicide, for example.

A prevention layer 130 may be formed on the mask layer 120. The prevention layer 130 may be formed of chromium. Because the mask layer 120 is formed of molybdenum silicide having, in exemplary embodiments in accordance with principles of inventive concepts, an optical transmissivity of about 6%, in accordance with principles of inventive concepts, a prevention pattern 130p may be added to the mask to prevent light from being transmitted through the peripheral region of the transparent substrate 110, as shown in FIG. 4J. The prevention layer 130 may be used to form the prevention pattern 130p. An added benefit of the prevention layer 130 is that it may prevent a charging effect of an electron beam in a process of etching the mask layer 120.

The first photoresist pattern 140 may be formed on the prevention layer 130 to expose a portion of each of the main region M and the supplementary region S and cover the peripheral region P, for example.

Referring to FIG. 4B, in exemplary embodiments in accordance with principles of inventive concepts, the prevention layer 130 may be etched using the first photoresist pattern 140 as an etch mask to form the main mask pattern 130m, the supplementary mask pattern 130s, and the prevention pattern 130p on the main region M, the supplementary region S, and the peripheral region P, respectively, of the mask layer 120.

Referring to FIGS. 4C through 4E, in exemplary embodiments in accordance with principles of inventive concepts, the first photoresist pattern 140 may be removed, and then a second photoresist layer 150 may be formed on the transparent substrate 110 provided with the main mask pattern 130m, the supplementary mask pattern 130s, and the prevention pattern 130p. The second photoresist layer 150 may be developed to form a second photoresist pattern 150a exposing the main region M and covering the supplementary region S and the peripheral region P, for example. On the main region M, the main mask pattern 130m may be exposed by the second photoresist pattern 150a.

Referring to FIGS. 4F through 4H, the mask layer 120 may be etched using the main mask pattern 130m exposed by the second photoresist pattern 150a as an etch mask to form the main pattern 120m and the peripheral pattern 120p. The main pattern 120m may be formed to have a sidewall that is perpendicular to the surface of the transparent substrate 110. That is, in accordance with principles of inventive concepts, sidewalls of the main pattern may be perpendicular to the surface of transparent substrate 110.

The second photoresist pattern 150a may be removed, and then, a third photoresist layer 160 may be formed on the transparent substrate 110 provided with the main pattern 120m.

The third photoresist layer 160 may be developed to form a third photoresist pattern 160a exposing the supplementary region S and covering the main region M and the peripheral region P. On the supplementary region S, the supplementary mask pattern 130s may be exposed by the third photoresist pattern 160a.

Referring to FIG. 4I, the mask layer 120 may be etched using the supplementary mask pattern 130s exposed by the third photoresist pattern 160a as an etch mask to form the supplementary pattern 120s. The supplementary pattern 120s may be formed to have a sidewall inclined to the surface of the transparent substrate 110. That is, in accordance with principles of inventive concepts, sidewalls of supplementary pattern 120s may not be perpendicular to the surface of transparent substrate 110 and may, in exemplary embodiments, be at an angle of from about 5□ to about 45□ with a perpendicular to the surface of transparent substrate 110, for example. For example, the supplementary pattern 120s, or elements thereof, may be formed to have a width decreasing with increasing distance from the transparent substrate 110. In example embodiments, the angle between the sidewall of the supplementary pattern 120s and the surface of the transparent substrate 110 may range from 45° to 85°.

The formation of the supplementary pattern 120s may be performed by an etching process using an etch recipe different from that for forming the main pattern 120m. For example, between the etching processes for forming the supplementary pattern 120s and the main pattern 120m, there may be a difference in a process condition associated with an etch bias. This difference may allow the formation of inclined sidewalls of the supplementary pattern 120s in accordance with principles of inventive concepts.

Referring to FIG. 4J, the third photoresist pattern 160a may be removed, and then, the main mask pattern 130m and the supplementary mask pattern 130s may be removed from the main region M and the supplementary region S, respectively. The removal of the main mask pattern 130m and the supplementary mask pattern 130s may be performed using an etch-back process, for example.

After the removal of the main and supplementary mask patterns 130m and 130s, a cleaning process may be performed on the mask, including the main pattern 120m, the supplementary pattern 120s, the peripheral pattern 120p, and the prevention pattern 130p provided on the transparent substrate 110.

Because, in exemplary embodiments in accordance with principles of inventive concepts, the supplementary pattern 120s, or elements thereof, includes sidewalls formed at an incline to the surface of transparent substrate 110, the supplementary pattern 120s may better endure a cleaning process. That is, with the width (and cross-sectional area) of the supplementary patter 120s decreasing with increasing distance from the transparent substrate 110 (exhibiting an upward tapered structure), the supplementary pattern 120s can have an improved endurance to the cleaning process, because, for example, due to the upward-tapered shape, the supplementary pattern 120s may not detach during the cleaning process.

According to the afore-described method of fabricating a mask, the supplementary pattern, or elements thereof, may be formed to have the width decreasing with increasing distance from the transparent substrate, or, in other words, exhibiting an upward tapered structure. Accordingly, the supplementary pattern can have an improved endurance to a cleaning process and, as a result, the use of the mask fabricated by a method in accordance with principles of inventive concepts makes it possible to improve resolution in a photolithography process using an optical proximity process that includes a formation of a supplementary pattern. In exemplary embodiments in accordance with principles of inventive concepts, a supplementary pattern employed in an optical proximity correction process may employ sidewalls that are not perpendicular to the surface of a transparent substrate. By thus reducing the aspect ratio of the supplemental pattern, the supplemental pattern is more likely to remain intact after a cleaning process with might otherwise damage or remove a supplemental pattern having sidewalls that are perpendicular to the surface of a photo-mask's transparent substrate. An intact supplemental pattern, such as may be allowed using a process in accordance with principles of inventive concepts, will operate more effectively to improve compensation for image errors due to diffraction or process effects in the process of semiconductor manufacturing, for example

While exemplary embodiments in accordance with principles of inventive concepts have been shown and described, it will be understood that variations in form and detail may be made therein without departing from the spirit and scope of inventive concepts as set forth in the attached claims.

1.-5. (canceled)

6. A method of fabricating a photo mask, comprising:
preparing a transparent substrate including a main region, a supplementary region adjacent to the main region, and a peripheral region surrounding the main region and the supplementary region; and
forming a main pattern, a supplementary pattern, and a prevention pattern on the main region, the supplementary region, and the peripheral region, respectively, of the transparent substrate,
wherein the main pattern is formed to have a sidewall perpendicular to a surface of the transparent substrate, and
the supplementary pattern is formed to have a sidewall inclined to the surface of the transparent substrate to form an upward tapered structure.

7. The method of claim 6, wherein the angle between the surface of the transparent substrate and the sidewall of the supplementary pattern is from 45° to 85°.

8. The method of claim 6, wherein the forming of the main pattern, the supplementary pattern, and the prevention pattern comprises:
forming a mask layer on the transparent substrate;
forming a first photoresist pattern on the mask layer to expose a portion of the main region and cover the supplementary region and the peripheral region;
etching the mask layer using the first photoresist pattern as a mask to form the main pattern and the prevention pattern;
removing the first photoresist pattern;
forming a second photoresist pattern on the transparent substrate, in which with the main pattern and the prevention pattern are formed, to expose a portion of the supplementary region and cover the main region and the peripheral region;
etching the mask layer using the second photoresist pattern as a mask to form the supplementary pattern; and
removing the second photoresist pattern.

9. The method of claim 8, wherein the mask layer is formed of chromium or molybdenum silicide.

10. The method of claim 8, wherein the mask layer is formed of molybdenum silicide, and the method further comprises forming a prevention layer on the mask layer, before forming the first photoresist pattern.

11. The method of claim 10, wherein the prevention layer is formed of chromium.

12. The method of claim 10, further comprising:
forming a third photoresist pattern on the prevention layer to expose a portion of the main region and a portion of the supplementary region and cover the peripheral region;
etching the prevention layer using the third photoresist pattern as a mask to form a main mask pattern, a supplementary mask pattern and an additional prevention pattern on the main region, the supplementary region, and the peripheral region, respectively, of the mask layer; and
removing the third photoresist pattern.

13. The method of claim 12, wherein the forming of the main pattern comprises etching the mask layer using the main mask pattern and the first photoresist pattern wholly exposing the main region as an etch mask.

14. The method of claim 12, wherein the forming of the supplementary pattern comprises etching the mask layer using the supplementary mask pattern and the second photoresist pattern wholly exposing the supplementary region as an etch mask.

15. The method of claim 12, after the removing of the third photoresist pattern, further comprising removing the main mask pattern on the main pattern and the supplementary mask pattern on the supplementary pattern.

16.-20. (canceled)
